(19) United States
(12) Patent Application Publication
(10) Pub. No.: US 2016/0268530 A1
(43) Pub. Date: Sep. 15, 2016

(54) PHOTOELECTRIC CONVERSION ELEMENT AND SOLAR CELL

(71) Applicant: Kabushiki Kaisha Toshiba, Minato-ku (JP)

(72) Inventors: Akihiro MATSUI, Chigasaki (JP); Takeshi GOTANDA, Yokohama (JP); Kenji TODORI, Yokohama (JP)

(73) Assignee: Kabushiki Kaisha Toshiba, Minato-ku (JP)

(21) Appl. No.: 15/062,279

(22) Filed: Mar. 7, 2016

(30) Foreign Application Priority Data
Mar. 10, 2015 (JP) 2015-047349

(51) Int. Cl. H01L 51/42; H01L 51/44

(52) U.S. Cl. CPC H01L 51/4213; H01L 51/442; H01L 51/0077

(57) ABSTRACT

The present disclosure provides a photoelectric conversion element having high conversion efficiency. In the photoelectric conversion element, a transparent substrate, a transparent electrode, an electron transfer layer, a photoelectric conversion layer and a back electrode are stacked in this order. The electron transfer layer contains cesium ions and has a minimum thickness of 1 to 16 nm.

### CROSS-REFERENCE TO RELATED APPLICATIONS

This application is based upon and claims the benefit of priority from the prior Japanese Patent Application No. 2015-047349, filed on Mar. 10, 2015, the entire contents of which are incorporated herein by reference.

### FIELD

Embodiments of the present disclosure relate to a photoelectric conversion element.

### BACKGROUND

Photoelectric conversion elements, which are typified by solar cells, have attracted attention as devices capable of providing clean energy, and hence various improvements have been attempted. For example, for the purpose of obtaining larger energy, it has been studied to improve photoelectric conversion efficiencies of the elements. In order to realize the improvement of conversion efficiency, it is first of all important to make a photoelectric conversion layer, which can be said to be an essential part of a photoelectric conversion element, absorb as much photo-energy as possible and thereby generate as many electrons and holes as possible. Further, it is also necessary to transfer the generated electrons and holes efficiently into the electrodes.

The electrons or holes generated in the photoelectric conversion layer can be efficiently transferred into the electrode by providing an intermediate layer between the conversion layer and the electrode. This intermediate layer is thus often referred to as “electron transport layer” or “hole transport layer”. If the electron transport layer, through which the electrons generated in the conversion layer are transferred into the electrode, is made of suitable materials and also controlled to have an appropriate thickness, it enables the electrons to migrate efficiently into the electrode.

As the materials for the electron transport layer, various substances have been studied. Examples of them include organic substances, such as oxazole derivatives and triazole derivatives, and inorganic substances, such as salts and oxides of metals. In addition, the layer constitution and thickness thereof have been also researched so as to realize efficient migration of the electrons.

However, the present applicant has found that any conventional photoelectric conversion element comprising an electron transport layer containing cesium ions is not improved enough to realize efficient electron migration and also that conversion elements like that are difficult to produce in a good yield. This is presumed to be because the evaluation method of the transport layer thickness is not established and hence the thickness cannot be precisely measured and controlled. Although prior researches have paid the attention to the average thickness of the electron transport layer, the conditions for forming a continuous even electron transport layer cannot be fully satisfied only by the average thickness because there is nanometer-order unevenness on the surface of the transparent electrode layer. As a result, short circuits may occur in some local areas, so that the electrons often cannot be extracted efficiently enough to realize a high yield.

### BRIEF DESCRIPTION OF THE DRAWINGS

FIG. 1 is a schematic sectional view illustrating a photoelectric conversion element according to the embodiment.

FIG. 2 is a sectional transmission electron micrograph (magnification: 3500000 times) of a photoelectric conversion element according to the embodiment.

FIG. 3 illustrates a method for measuring the thickness of electron transport layer on the basis of the sectional transmission electron micrograph of a photoelectric conversion element according to the embodiment.

FIG. 4 shows correlations between the minimum layer thicknesses and the conversion efficiencies of photoelectric conversion elements in Examples and Comparative examples.

### DETAILED DESCRIPTION

A photoelectric conversion element according to the embodiment comprises,

a transparent substrate,
a transparent electrode,
an electron transfer layer,
a photoelectric conversion layer, and
a back electrode
which are stacked in this order;
wherein said electron transfer layer contains cesium ions and has a minimum thickness of 1 to 16 nm.

Embodiments will now be explained with reference to the accompanying drawings.

FIG. 1 is a schematic sectional view illustrating a photoelectric conversion element according to the embodiment. The figure shows a transparent electrode 1, an electron transport layer 2, a photoelectric conversion layer 3, a hole transport layer 4, and a back electrode 5, which are stacked on a transparent substrate 6. In the present embodiment, the hole transport layer is dispensable and hence can be omitted. The transparent electrode 1 and the back electrode 5 serve as a cathode and an anode, from which electrons and holes are extracted, respectively. The photoelectric conversion layer 3 is excited by incident light coming through the transparent substrate 6, the transparent electrode 1 and the electron transport layer 2, to generate electrons and holes, which are then distributed to the transparent electrode 1 and the back electrode 5, respectively. The electron transport layer 2 or the hole transport layer 4 is sandwiched between the photoelectric conversion layer and the cathode or anode, respectively.

Those constituting members of the photoelectric conversion element according to the embodiment are individually explained below.

### (Transparent Substrate 6)

The transparent substrate 6 has a function of supporting other members, and can be freely selected from substrates or supporting parts used in conventional photoelectric conversion elements. However, since incident light needs to reach the photoelectric conversion layer through the transparent substrate, it must be transparent or semitransparent.

The transparent substrate 6 has a surface on which the electrode can be formed, and hence is preferably not impaired by heat or organic solvents. The transparent substrate 6 may be made of inorganic materials or organic materials. Examples of the inorganic materials include non-alkali glass and quartz glass. Examples of the organic materials include plastics, such as, polyethylene, polyethylene terephthalate (PET), polyethylene naphthalate (PEN), polyimide, polyamide, poly-amide-imide, polyester, and polycycloolefin. Those organic materials may be in the form of liquid crystal polymer or polymer films.

The thickness of the substrate is not particularly restricted as long as the substrate has strength enough to support other constituting members. For example, the substrate can be made of flexible materials. Further, since positioned on the light-incident side, the transparent substrate 6 may be coated with, for example, an antireflective film with a moth eye structure formed on the light-incident surface. The antireflective film enables incident light to enter the element efficiently and thereby can improve the energy conversion efficiency of the photoelectric conversion element. Here, the “moth eye structure” means a structure having a surface on which convexes of about 100 nm height are regularly arranged. Because of this convex structure, the refractive index continuously changes along the thickness direction of the film. Accordingly, if the substrate is coated with the antireflective film, the film prevents the refractive index from discontinuous changing. Consequently, the film reduces reflection of the incident light and thereby improves the conversion efficiency of the element.

### (Transparent Electrode 1)

The transparent electrode 1 may be either transparent or semitransparent and the material thereof is not particularly restricted as long as it is both electroconductive and light-passable. Accordingly, the transparent or semitransparent material for the electrode can be freely selected from materials or substances used in known photoelectric conversion elements. For example, electroconductive metal oxides or semitransparent metals are employable. Examples of them include indium oxide, zinc oxide, tin oxide (NESA), composites thereof, such as, indium-tin oxide (ITO), fluorine-doped tin oxide (FTO), and indium-zinc oxide (IZO), and metals, such as, gold, platinum, silver, and copper. Particularly preferred are ITO and FTO. Further, organic electroconductive polymers, such as, polyaniline and derivatives thereof, and polythiophene and derivatives thereof, also can be adopted as the electrode material.

The transparent electrode can be produced by forming a film of the above material on the surface of the transparent substrate 6 according to, for example, vapor-deposition, sputtering, ion-plating, normal plating or wet-coating.

In the case where the transparent electrode is made of ITO, the minimum thickness thereof is preferably 30 to 300 nm. The minimum thickness of 30 nm or more makes the electroconductivity tend to be large enough to enhance the photoelectric conversion efficiency. On the other hand, the minimum thickness of 300 nm or less enables the ITO film serving as the transparent electrode to have such flexibility that the electrode hardly suffers from cracks and the like even if stress is applied. The transparent electrode preferably has as small a sheet resistance as possible. Specifically, the sheet resistance is preferably 10 Ω/square or less. The transparent electrode may be a single layer, but it may consist of stacked plural layers made of materials having different work functions. Further, if necessary, it may be a transparent electrode layer combined with a wire-shaped electrode.

### (Electron Transport Layer 2)

In the photoelectric conversion element of the present embodiment, the electron transport layer contains cesium ions. The cesium ions can be introduced into the transport layer by adopting a cesium ion-containing material.

The cesium ion-containing material can be freely selected, but cesium ion-containing ionic compounds are generally used. There are no particular restrictions on the counter anions contained in those ionic compounds. Examples of the cesium ion-containing material include inorganic salts, such as, cesium carbonate, cesium fluoride, cesium chloride, cesium bromide, cesium iodide, cesium sulfate, and cesium nitrate; and organic salts, such as, cesium acetate and cesium formate. A mixture of these compounds can be used. Among them, cesium carbonate is particularly preferred.

The electron transport layer in the embodiment may also contain other materials as long as it contains a cesium ion-containing material. For example, the layer may contain salts of cations other than cesium ion or double salts of cesium ion and metal ions other than cesium ion. Further, the electron transport layer generally can comprise a binder and the like in addition to the above ionic compounds. However, in order to ensure high electroconductivity, the materials other than the cesium ion-containing material are incorporated preferably in small amounts. The content of the cesium ions is preferably 60 to 90 wt % based on the total weight of the electron transport layer.

The electron transport layer has a minimum thickness of preferably 1 to 16 nm, more preferably 2.3 to 9.0 nm. If the minimum thickness is 1 nm or more, the electron transport layer can be precisely and homogeneously formed. This effect is apparent when the minimum thickness is 2.0 nm or more. As a result, it becomes possible to prevent short circuits between the transparent electrode and the photoelectric conversion layer and accordingly to extract sufficient electric charge into the external circuit. On the other hand, if the minimum thickness is 16 nm or less, the resistance of the electron transport layer can be kept low enough to transfer a sufficient amount of generated electric charge into the external circuit. The effect of reducing the resistance is apparent and accordingly the conversion efficiency is dramatically improved particularly when the minimum thickness is 9.0 nm or less, and hence it is preferred.

The thickness of the electron transport layer 2 can be determined by the steps of: thinning the element into a thickness of, for example, 0.1 μm; sectioning the thinned element; taking an electron micrograph of the sectioned surface by use of an electron microscope, such as, a transmission electron microscope (TEM); and then analyzing the obtained micrographic image. Specifically, in this image analysis, the interfaces among the photoelectric conversion layer, the electron transport layer and the transparent electrode are determined and then the thickness of the electron transport layer is measured perpendicularly to the layers. As described above, the electron transport layer does not have completely even thickness, and hence the thickness is measured at plural positions, for example, at 100 positions and the smallest value thereof is regarded as the minimum thickness. Moreover, it is also possible to obtain an average thickness from the measured values. In addition, if the image analysis is carried out in combination with chemical element analysis, the interfaces among the layers and the thickness of the electron transport layer 2 can be further clearly determined.

The electron transport layer can be formed in any manner. For example, it can be produced by vapor deposition in a vapor deposition system. Further, it also can be formed by a wet-coating process comprising the steps of: dissolving a cesium ion-containing material in a solvent to prepare a coating solution, and then applying the solution. This wet-coating process is simple and hence preferred. Specifically, if adopted as the cesium ion-containing material, cesium carbonate is preferably so dissolved in 2-ethoxyethanol that the concentration may be 2 mg/ml to prepare a coating solution, which is then applied. The applied solution is preferably heated at 20 to 200° C. to remove the solvent, so that the electron transport layer can be formed.

### (Photoelectric Conversion Layer 3)

The photoelectric conversion element of the embodiment comprises a photoelectric conversion layer. The photoelectric conversion layer is not particularly restricted as long as it can generate electricity from incident light, but typically contains an organic semiconductor material or an organic-inorganic hybrid material of perovskite structure.

When used in the photoelectric conversion layer, the organic semiconductor material may have a heterojunction structure or a bulk heterojunction structure. The bulk heterojunction structure is characterized in that p- and n-type semiconductors are mixed in the conversion layer to create a micro layer separation structure. The mixed p- and n-type semiconductors form p-n junctions of nano-order size in the photoelectric conversion layer, and electric currents can be obtained by use of photocharge separation induced at the junction surfaces. The p- and n-type semiconductors are made of electron-donating and electron-accepting materials, respectively. If an organic semiconductor material is adopted in the conversion layer of the embodiment, at least one of either the p-type semiconductor or the n-type semiconductor is preferably an organic semiconductor.

Examples of the p-type organic semiconductor include polythiophene and derivatives thereof, polypyrrole and derivatives thereof, pyrazoline derivatives, arylamine derivatives, stilbene derivatives, triphenyldiamine derivatives, oligo-thiophene and derivatives thereof, polyvinyl carbazole and derivatives thereof, polysilane and derivatives thereof, polysiloxane derivatives having aromatic amines in their main or side chains, polyaniline and derivatives thereof, phthalocyanine derivatives, porphyrin and derivatives thereof, polyphenylene-vinylene and derivatives thereof, polythienylenevinylene and derivatives thereof, benzodithiophene and derivatives thereof, thieno[3,2-b]thiophene and derivatives thereof, and combinations of those substances. Further, it is also possible to use copolymers thereof, such as, thiophene-fluorene copolymer, phenylene ethynylene-phenylene vinylene copolymer, and benzodithiophene-thieno[3,2-b]thiophene copolymer.

Preferred p-type organic semiconductors are electroconductive polymers containing n-conjugated systems, such as, polythiophene and derivatives thereof, which ensure excellent steric regularity and have relatively high solubility to solvents. The polythiophene and derivatives thereof are not particularly restricted as long as they have thiophene skeletons. Examples of the polythiophene and derivatives thereof include: (i) polyalkylthiophenes (hereinafter often referred to as “P3AT”), such as, poly3-methylthiophene, poly3-butylthiophene, poly3-hexylthiophene, poly3-octylthiophene, poly3-decyl-thiophene, and poly3-dodecylthiophene; (ii) polyarylthiophenes, such as, poly3-phenylthiophene, and poly3-(p-alkylphenyl-thiophene); (iii) polyalkylisothionaphthenes, such as, poly-3-butylisothionaphthene, poly3-hexylisothionaphthene, poly3-octylisothionaphthene, and poly3-decylisothionaphthene; and (iv) polyethylenedioxythiophene.

Further, recently, other derivatives, such as, PCDTBT (poly[N-9″-hepta-decanyl-2,7-carbazole-alt-5,5-(4′,7′-di-2-thienyl-2′,1′,3′-benzothiadiazole)]), which is a copolymer of carbazole, benzothiadiazole and thiophene, have been known as compounds capable of realizing excellent photoelectric conversion efficiency.

Furthermore, also preferred are copolymers of benzodithiophene (BDT) derivatives and thieno[3,2-b]thiophene derivatives. Preferred examples thereof include: poly[4,8-bis[(2-ethylhexyl)oxy]benzo[1,2-b:4-5-b′]dithiophene-2,6-dyl][3-fluoro-2-[(2-ethylhexyl)carbonyl]thieno[3,4-b]-thiophenedyl]] (often referred to as “PTB7”); and poly[4,8-bis-[5-(2-ethylhexylthiophene-2-yl)benzo[1,2-b:4-5-b′]dithiophene-co-3-fluorothieno[3,4-b]thiophene-2-carboxylate] (often referred to as “PTB7-Th” or “PBDTTT-EFT), which contains thienyl group having weaker electron donatability than the alkoxy group in PTB7.

As the n-type semiconductor, fullerene and derivatives thereof are preferably adopted. The fullerene derivatives are not particularly restricted as long as they have fullerene skeletons. Examples thereof include derivatives having basic skeletons of C60, C70, C76, C78 or C84. In those fullerene derivatives, carbon atoms in the fullerene skeletons may be modified with any functional groups, which may connect to each other to form ring structures. The fullerene derivatives include fullerene-containing polymers. The fullerene derivatives preferably contain functional groups having enough high compatibility with solvents to be very soluble therein.

Examples of the functional groups in the fullerene derivatives include: (i) hydrogen atom; (ii) hydroxyl group; (iii) halogen atoms, such as, fluorine and chlorine; (iv) alkyl groups, such as, methyl and ethyl; (v) alkenyl groups, such as, vinyl; (vi) cyano group; (vii) alkoxy groups, such as, methoxy and ethoxy; (viii) aromatic hydrocarbon groups, such as, phenyl and naphthyl; and (ix) aromatic heterocyclic groups, such as, thienyl and naphthyl. Concrete examples of the fullerene derivatives include: hydrogenated fullerenes, such as, C60H36 and C70H36; oxide fullerenes having basic skeletons of C60, C70 and the like; and fullerene metal complexes.

Among the above, it is particularly preferred to use 60PCBM ([6,6]-phenylC61butyric methyl ester) or 70PCBM ([6,6]-phenylC71butyric methyl ester) as the fullerene derivative.

Further, an unsubstituted fullerene C70 is also preferably used because it efficiently generates photocarriers and hence is suitably used in an organic thin-film solar cell.

There are no particular restrictions on the mixing ratio between the n- and p-type organic semiconductors in the photoelectric conversion layer. However, if the p-type semiconductor is P3AT or the like, the ratio of p:n is preferably about 1:1 (by weight). If PCDTBT or the like is adopted as the p-type semiconductor, the ratio of p:n is preferably about 1:4 (by weight). If the p-type semiconductor is PBDTTT-EET or the like, the p:n is preferably about 1:2 (by weight).

Those organic semiconductors can be dissolved in solvents to prepare coating solutions, which are then applied to form layers. Accordingly, they have an advantage in that large-scaled organic thin-film solar cells can be produced by a printing process at low cost with inexpensive facilities.

For applying the organic semiconductors, they need to be dissolved in solvents. Examples of the solvents include: (i) unsaturated hydrocarbons, such as, toluene, xylene, tetracene, decalin, mesitylene, n-butylbenzene, sec-butylbenzene, and tert-butylbenzene; (ii) halogenated aromatic hydrocarbons, such as, chlorobenzene, dichlorobenzene, and trichlorobenzene; (iii) halogenated saturated hydrocarbons, such as, tetrachlorocarbon, chloroform, dichloromethane, dichloroethane, chlorobutane, bromobutane, chloropentane, chlorohexane, bromohexane, and chlorocyclohexane; and (iv) ethers, such as, tetrahydrofuran and tetrahydropyran. Particularly preferred are halogenated aromatic hydrocarbons. Those solvents can be use singly or in combination.

The coating solution can be applied by, for example, spin coating, dip coating, casting, bar coating, roll coating, wire-bar coating, spraying, screen printing, gravure printing, flexo printing, offset printing, gravure offset printing, dispenser application, nozzle coating, capillary coating, or ink-jet method. In the embodiment, those coating method can be used singly or in combination.

It is also possible in the embodiment to use an organic-inorganic hybrid material of perovskite structure in the photoelectric conversion layer. The organic-inorganic hybrid material of perovskite structure comprises ions A, B and X, and can be represented by the formula ABX3. If the ion B is smaller than the ion A, the hybrid material may have a perovskite structure. This material has a unit lattice belonging to the cubic crystal system, and the ions A, B and X are positioned at the vertexes, body centers and face centers, respectively, in the cubic crystal lattices. Each BX6 octahedron is easily distorted by interaction with the ions A. Accordingly, the symmetry tends to be lowered and hence to induce a Mott transition, so that valence electrons localized around the ions M can be spread in a band. The ion A is preferably CH₃NH₃, the ion B is preferably Pb or Sn, and the ion X is preferably Cl, Br or I. Each of the ions A, B and X constituting the perovskite structure may be a single species or a mixture of some species.

### (Hole Transport Layer 4)

In the embodiment, the hole transport layer 4 is dispensable. However, if provided in the photoelectric conversion element of the embodiment, the hole transport layer is preferably made of a material having a work function close to that of the back electrode 5 described later. Preferred examples of the material include oxides of titanium, molybdenum, vanadium, zinc, nickel, lithium, calcium, cesium, aluminum, gallium, magnesium, and cadmium. Those oxides may used in combination of two or more. The hole transport layer has a minimum thickness of generally 1 to 500 nm, preferably 2 to 300 nm. If the minimum thickness is 500 nm or less, the resistance can be kept low enough to transfer a sufficient amount of generated electric charge into the external circuit. It is hence preferred. Further, the hole transport layer having a small thickness can be formed in a short time. This means that the material thereof can be exposed to high temperature in a time short enough to avoid deterioration. Furthermore, in view of the production cost, the hole transport layer preferably has a small thickness.

### (Back Electrode 5)

The back electrode 5 is not particularly restricted as long as it has electroconductivity. In consideration of optical management, the back electrode is preferably made of such opaque metal as can reflect the incident light to use effectively. The back electrode also can be made of a transparent or semitransparent material so as to produce a see-through type photoelectric conversion element. Further, for the purpose of introducing the incident light from the back electrode side, the back electrode can be made of a transparent or semitransparent electroconductive material.

Examples of the opaque metal include metals such as, gold, silver, platinum, copper, manganese, titanium, cobalt, nickel, tungsten and thin, and alloys containing them. Examples of the alloys include lithium-aluminum alloy, lithium-manganese alloy, lithium-indium alloy, manganese-silver alloy, calcium-indium alloy, manganese-aluminum alloy, indium-silver alloy, and calcium-aluminum alloy. The transparent or semitransparent electrode can be made of, for example, electroconductive metal oxide or semitransparent metal. Examples thereof include indium oxide, zinc oxide, tin oxide (NESA), and composites thereof, such as, indium-tin oxide (ITO), fluorine-doped tin oxide (FTO), and indium-zinc oxide (IZO). Further, it is also possible to adopt organic substances, such as, electroconductive polymers.

The back electrode can be produced according to, for example, vapor-deposition, sputtering, ion-plating, normal plating or wet-coating. There are no particular restrictions on the thickness. However, if the opaque metal is adopted, the minimum thickness is preferably 100 nm or more in view of optical management. On the other hand, if intended to be transparent, the electrode is preferably made of ITO or FTO. The electrode also may be made of organic electroconductive polymers, such as, polyaniline and derivatives thereof, and polythiophene and derivatives thereof. If ITO is adopted, the minimum thickness is preferably 30 to 300 nm. The minimum thickness of 30 nm or more ensures enough high electroconductivity to improve the photoelectric conversion efficiency. On the other hand, the minimum thickness of 300 nm or less enables the ITO film to have enough flexibility to avoid cracks even if stress is applied. The minimum thickness in the above range is thus preferred. The electrode preferably has as small a sheet resistance as possible. Specifically, the sheet resistance is preferably 10 Ω/square or less. The back electrode may be a single layer, but it may consist of stacked plural layers made of materials having different work functions.

### (Practical Application of Photoelectric Conversion Element)

The photoelectric conversion element of the embodiment can be employed in any known devices. Typically, it can be used in solar cells, particularly, organic thin-film solar cells and a solar panel or a cell module. Further, the conversion element of the embodiment can be also installed in optical sensors or imaging devices. For example, a plural number of the elements according to the embodiment are two-dimensionally arranged to function as an imaging device. Further, they may be linearly aligned to serve as a scanner.

### EXAMPLES

### Example 1

A photoelectric conversion element was produced in the following manner. In the element, the substrate 6 was a glass plate. The transparent electrode 1, the electron transport layer 2, the photoelectric conversion layer 3, the hole transport layer 4, and the back electrode 5 were made of ITO, cesium carbonate, a mixture of PBDTTT-EFT as the p-type organic semiconductor material and [60]PCBM as the n-type organic semiconductor material, V₂O₅, and Ag, respectively.

On the glass plate 6, ITO was sputtered to form the transparent electrode 1, which was then coated with a 2 mg/mL 2-ethoxyethanol solution of Cs₂CO₃ by spin-coating at 7000 rpm under nitrogen atmosphere. The obtained coat was dried at 150° C. for 20 minutes to form the electron transport layer 2.

The electron transport layer 2 was further coated with a 20 mg/ml solution of PBDTTT-EFT and [60]PCBM by spin-coating at 700 rpm. This solution contained PBDTTT-EFT and [60]PCBM in a ratio of 1:2 by weight, and the solvent thereof was chlorobenzene containing DIO in an amount of 3% by weight. From the obtained coat, the solvent was then removed in a vacuum deposition system to form the photoelectric conversion layer 3.

Successively, V₂O₅ was deposited thereon in the vacuum deposition system to form the hole transport layer of 2 nm thickness. Further, Ag was deposited thereon in the vacuum deposition system to form the back electrode of 120 nm thickness. In this manner, a photoelectric conversion element was produced.

For evaluating the PCE (power conversion efficiency) of the produced element, the I-V characteristics were measured between the transparent electrode 1 and the back electrode 5. Specifically, while the element was kept exposed to light under the conditions of 1 sun (AM1.5, 100 mW/cm²) or low illuminance (500 lux), the current and voltage were measured between the electrodes. In the measurement under the low illuminance conditions, a lighting box (LLBG1-FA-20x30-TSK™, manufactured by AI TECH SYSTEMS Co., Ltd.) was adopted as the light source and the illuminance was monitored with a spectroradiometer (MS-720 ™, manufactured by EKO INSTRUMENTS Co., Ltd.).

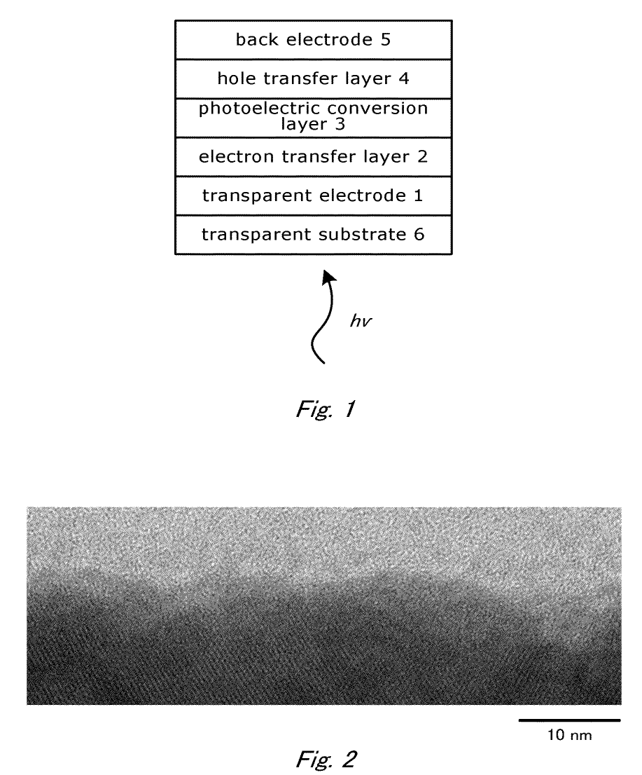

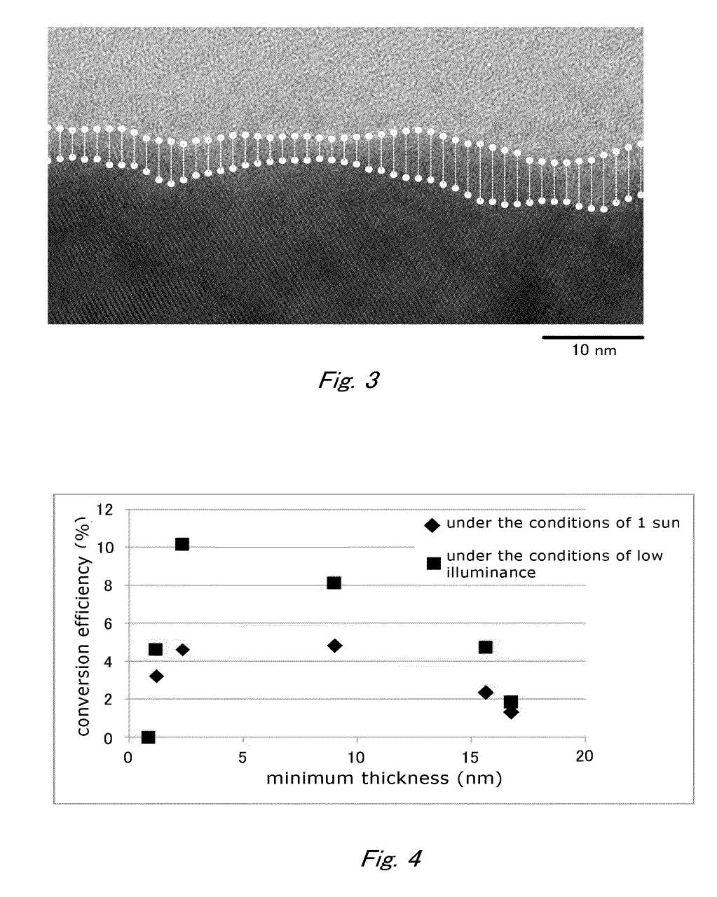

Meanwhile, the thickness of the electron transport layer 2 was estimated from sectional micrographic images (magnification: 3500000 times) of the element beforehand thinned into a thickness of 0.1 μm. The micrographic images were taken by use of a TEM system (H9500 type™, manufactured by Hitachi High-Technologies Corporation). FIG. 2 shows an example of the sectional micrographic images of the photoelectric conversion element according to the embodiment. The minimum thickness was obtained by the steps of: determining the interfaces among the conversion layer, the electron transport layer and the transparent electrode layer on the basis of contrast differences in one of the sectional images; measuring the transport layer thickness vertically to the layers at every interval of 1 to 1.5 nm in the horizontal direction (see, FIG. 3); repeating the above steps in other ten TEM images; and regarding the thinnest of the obtained thicknesses as the minimum thickness. In the element of Example 1, the electron transport layer was found to have a minimum thickness of 2.33 nm

### Examples 2 to 4 and Comparative Examples 1 and 2

The procedure of Example 1 was repeated except for changing the process for forming the electron transport layer 2, to produce photoelectric conversion elements of Examples 2 to 4 and Comparative examples 1 and 2. Specifically, in forming the electron transport layer 2, the concentration of the coating solution was changed in the range of 0.5 to 2 mg/nil and then the solution was applied by spin-coating at 500 to 7000 rpm. The coating conditions were thus changed to form electron transport layers having different thicknesses. With respect to each of the produced elements, the minimum thickness of the electron transport layer was measured and further the conversion efficiency was also measured under the conditions of 1 sun or low illuminance. The resultant minimum thicknesses and conversion efficiencies are shown in Table 1 and FIG. 4.

TABLE 1

| | Minimum | Conversion efficiency (%) | | |
|---|---|---|---|---|
| | thickness | | low | |
| | (nm) | 1 sun | illuminance | Remarks |
| Example 1 | 2.33 | 4.63 | 10.21 | |
| Example 2 | 9.00 | 4.85 | 8.17 | |
| Example 3 | 15.65 | 2.36 | 4.77 | |
| Example 4 | 1.17 | 3.23 | 4.62 | |
| Comparative | 0.58 | — | — | no electricity |
| Example 1 | | | | generation |
| Comparative | 16.77 | 1.35 | 1.86 | |
| Example 2 | | | | |

### [Evaluation of Production Stability]

The procedure of Example 1 was repeated except for changing the process for forming the electron transport layer 2, to produce a plural number of photoelectric conversion elements. The minimum thicknesses of the electron transport layers in the produced elements were measured and consequently found to be distributed in a wide range. Further, the conversion elements were individually checked whether or not they could generate electricity, and thereby correlations of the electric generating capability with the minimum and average thicknesses were evaluated. As a result, if the electron transport layers had minimum thicknesses of more than 16 nm, almost all the elements were able to generate electricity. Accordingly, it was verified that short circuits rarely occur if the electron transport layer is thickened. On the other hand, however, the thicker the electron transport layers were, the lower the conversion efficiencies tended to be.

Some of the elements which comprises the electron transport layers having minimum thicknesses of 16 nm or less were unable to generate electricity. Specifically, if the minimum thicknesses were less than 1 nm, the elements were generally incapable of generating electricity. For the elements which comprises the electron transport layers having minimum thicknesses of less than 1 nm, it was impossible to generate electricity even if the average thicknesses were about 10 nm. In contrast, if the minimum thicknesses were 1 nm or more, the elements can scarcely generate electricity. If the minimum thicknesses were 2.3 nm or more, a percentage of the element which cannot generate electricity is further reduced. From those results, it was verified that the minimum thickness is more important than the average thickness in view of the production yield, also that the minimum thickness is necessarily 1 nm or more and still also that the minimum thickness of 2.3 nm or more provides favorable effects. In addition, it was further verified that the minimum thickness of 16 nm or less enables the element to achieve sufficient conversion efficiency and also that the minimum thickness of 9.0 nm or less provides remarkable improvement.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fail within the scope and sprit of the invention.

1. A photoelectric conversion element comprising a transparent substrate,
a transparent electrode,
an electron transfer layer,
a photoelectric conversion layer, and
a back electrode
which are stacked in this order;
wherein said electron transfer layer contains cesium ions and has a minimum thickness of 1 to 16 nm.

2. The photoelectric conversion element according to claim 1, wherein said electron transfer layer comprises a material selected from the group consisting of cesium carbonate, cesium fluoride, cesium chloride, cesium bromide, cesium iodide, cesium sulfate, cesium nitrate, cesium acetate, cesium formate, and mixture thereof.

3. The photoelectric conversion element according to claim 1, wherein said electron transfer layer has a minimum thickness of 2.3 to 9.0 nm.

4. The photoelectric conversion element according to claim 1, which further comprises a hole transfer layer between said photoelectric conversion layer and said back electrode.

5. The photoelectric conversion element according to claim 1, wherein said photoelectric conversion layer contains an organic semiconductor material or an organic-inorganic hybrid material of perovskite structure.

6. A solar cell comprising the photoelectric conversion element according to claim 1.

7. A solar panel comprising a solar cell according to claim 6.
